(19) United States
(12) Patent Application Publication
(10) Pub. No.: US 2015/0123086 A1
(43) Pub. Date: May 7, 2015

(54) ORGANIC LIGHT EMITTING DIODE DISPLAY AND MANUFACTURING METHOD THEREOF

(71) Applicant: SAMSUNG DISPLAY CO., LTD., Yongin-City (KR)

(72) Inventors: Jae-Young Lee, Yongin-si (KR); Seong-Jun Lee, Suwon-si (KR); Seong-Jong Kang, Seongnam-si (KR); Myoung-Ki Kim, Hwaseong-si (KR); Byung-Hoon Chun, Yongin-si (KR)

(73) Assignee: SAMSUNG DISPLAY CO., LTD., Yongin-City (KR)

(21) Appl. No.: 14/275,746

(22) Filed: May 12, 2014

(30) Foreign Application Priority Data
Nov. 6, 2013 (KR) 10-2013-0133915

(51) Int. Cl. H01L 51/52; H01L 51/56

(52) U.S. Cl. CPC H01L 51/5275; H01L 51/56; H01L 51/5253
USPC 257/40; 438/26

(57) ABSTRACT

An organic light emitting diode display includes a first substrate, an organic light emitting diode on the first substrate, a capping layer on the organic light emitting diode. The capping layer includes a first surface facing the organic light emitting diode and a second surface opposite the first surface. The capping layer has a gradient of refractive index that varies along a thickness direction from the first surface toward the second surface.

### CROSS-REFERENCE TO RELATED APPLICATION

This application claims priority to and the benefit of Korean Patent Application No. 10-2013-0133915, filed on Nov. 6, 2013 with the Korean Intellectual Property Office, the disclosure of which is incorporated herein in its entirety by reference.

### BACKGROUND

1. Field

Aspects of embodiments of the present invention are directed toward an organic light emitting diode display and to a manufacturing method thereof.

2. Description of Related Art

An organic light emitting diode (OLED) display has recently drawn attention as a display device.

The organic light emitting diode display is a self-emission display device which has an organic light emitting diode that emits light to display an image. Unlike a liquid crystal display, the organic light emitting diode display does not require a separate light source, and thus, may have a relatively small thickness and light weight. Further, the organic light emitting diode display is in the spotlight as a next-generation display device by virtue of its features such as low power consumption, high luminance, and short response time.

The organic light emitting diode generally includes a hole injection electrode, an organic light emitting layer, and an electron injection electrode. In the organic light emitting diode, a hole supplied from the hole injection electrode and an electron supplied from the electron injection electrode are combined with each other in the organic light emitting layer to form an exciton, and light is emitted by energy generated when the exciton falls to a ground state.

In order to improve characteristics of the organic light emitting diode display, methods are currently utilized to improve light efficiency by more effective extraction of light generated from the organic light emitting layer.

### SUMMARY

Aspects of embodiments of the present invention are directed toward an organic light emitting diode display configured to effectively extract light generated in an organic light emitting layer.

Aspects of embodiments of the present invention also are directed toward an organic light emitting diode display having a capping layer with a gradient of refractive index.

Further, aspects of embodiments of the present invention are directed toward a manufacturing method of the organic light emitting diode display.

According to an embodiment of the present invention, an organic light emitting diode display includes a first substrate, an organic light emitting diode on the first substrate, and a capping layer on the organic light emitting diode, wherein the capping layer includes a first surface facing (e.g., toward) the organic light emitting diode and a second surface opposite the first surface (e.g., facing oppositely away from the organic light emitting diode), and wherein the capping layer has a refractive index that varies gradually (e.g., varies with a gradient of refractive index) along a thickness direction from the first surface toward the second surface.

The refractive index may increase along the thickness direction (that is, a direction from the first surface toward the second surface). The first surface may have a refractive index in a range of about 1.3 to about 1.8, and the second surface may have a refractive index in a range of about 1.8 to about 2.7.

The refractive index may decrease along the thickness direction (that is, a direction from the first surface toward the second surface). The first surface may have a refractive index in a range of about 1.8 to about 2.7, and the second surface may have a refractive index in a range of about 1.3 to about 1.8.

The refractive index of the capping layer may decrease from a point in the capping layer along a direction toward each of the first surface and the second surface, respectively.

The refractive index of the capping layer may increase from a point in the capping layer along a direction toward each of the first surface and the second surface, respectively.

The capping layer may include a first capping material, a second capping material having a refractive index higher than that of the first capping material, and a content ratio of the first capping material and the second capping material may gradually vary (e.g., may vary with a gradient of refractive index) along the thickness direction (that is, a direction from the first surface toward the second surface).

The refractive index of the capping layer may vary in a range of about 0.1 to about 1.0.

The organic light emitting diode display may further include a second substrate on the capping layer.

The organic light emitting diode display may further include a thin film encapsulation layer on the capping layer.

According to another embodiment of the present invention, a manufacturing method of an organic light emitting diode display includes forming an organic light emitting diode on a first substrate and forming a capping layer on the organic light emitting diode, wherein the forming of the capping layer includes depositing a first capping material and a second capping material having a refractive index higher than that of the first capping material on the organic light emitting diode, and a deposition ratio of the first capping material and the second capping material gradually varies (e.g., varies with a gradient) as the depositing is performed.

A deposition ratio of the first capping material may gradually increase as the depositing is performed.

A deposition ratio of the second capping material may gradually increase as the depositing is performed.

The first capping material may have a refractive index in a range of about 1.3 to about 1.8.

The second capping material may have a refractive index in a range of about 1.8 to about 2.7.

The forming of the capping layer may further include depositing a third capping material having a refractive index higher than that of the first capping material and lower than that of the second capping material.

The manufacturing method of an organic light emitting diode display may further include forming a thin film encapsulation layer on the capping layer after the forming of the capping layer.

The forming of the thin film encapsulation layer may include alternately forming an organic layer and an inorganic layer.

According to aspects of embodiments of the present invention, the organic light emitting diode display may have improved light extraction efficiency and white angular dependence characteristics because the capping layer has a gradient of refractive index.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The above and other features and aspects of the present invention will be more clearly understood from the following detailed description taken in conjunction with the accompanying drawings, in which:

FIG. 1 is a plan view showing an organic light emitting diode display according to an embodiment of the present invention;

FIG. 2 is a cross-sectional view taken along a line I-I′ of FIG. 1;

FIG. 3 is a schematic diagram of a configuration of a capping layer;

FIG. 4 is a schematic diagram showing a path of light propagating through a plurality of layers having different refractive indices;

FIG. 5 is a cross-sectional view of an organic light emitting diode display according to another embodiment of the present invention;

FIG. 6 a cross-sectional view of an organic light emitting diode display according to yet another embodiment of the present invention;

FIG. 7 is a schematic diagram showing a deposition apparatus according to an embodiment of the present invention;

FIG. 8 is a graph showing refractive index characteristics of deposition materials A, B, and C;

FIGS. 9A and 9B are graphs showing deposition profiles of two capping materials;

FIGS. 10A and 10B are schematic diagrams of configurations of the capping layers formed according to the deposition profiles shown in FIGS. 9A and 9B;

FIG. Ills a graph showing white angular dependence properties; and

FIG. 12 is a schematic diagram showing a deposition apparatus according to another embodiment of the present invention.

### DETAILED DESCRIPTION

Hereinafter, embodiments of the present invention will be described in detail with reference to the accompanying drawings. However, the scope of the present invention is not limited to the following drawings and embodiments.

In the drawings, certain elements or shapes may be simplified or exaggerated to better illustrate the present invention, and other elements present in an actual product may also be omitted. Thus, the drawings are intended to facilitate the understanding of the present invention. Like reference numerals refer to like elements throughout the specification.

It will be understood that when an element or layer is referred to as being “on,” “connected to”, or “coupled to” another element or layer, it can be directly on, connected, or coupled to the other element or layer, or one or more intervening elements or layers may also be present. When an element is referred to as being “directly on,” “directly connected to”, or “directly coupled to” another element or layer, there are no intervening elements or layers present. As used herein, the term “and/or” includes any and all combinations of one or more of the associated listed items. Further, the use of “may” when describing embodiments of the present invention relates to “one or more embodiments of the present invention”.

It will be understood that, although the terms first, second, third, etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein interpreted accordingly.

The terminology used herein is for the purpose of describing particular example embodiments only and is not intended to be limiting of example embodiments. As used herein, the singular forms “a,” “an”, and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

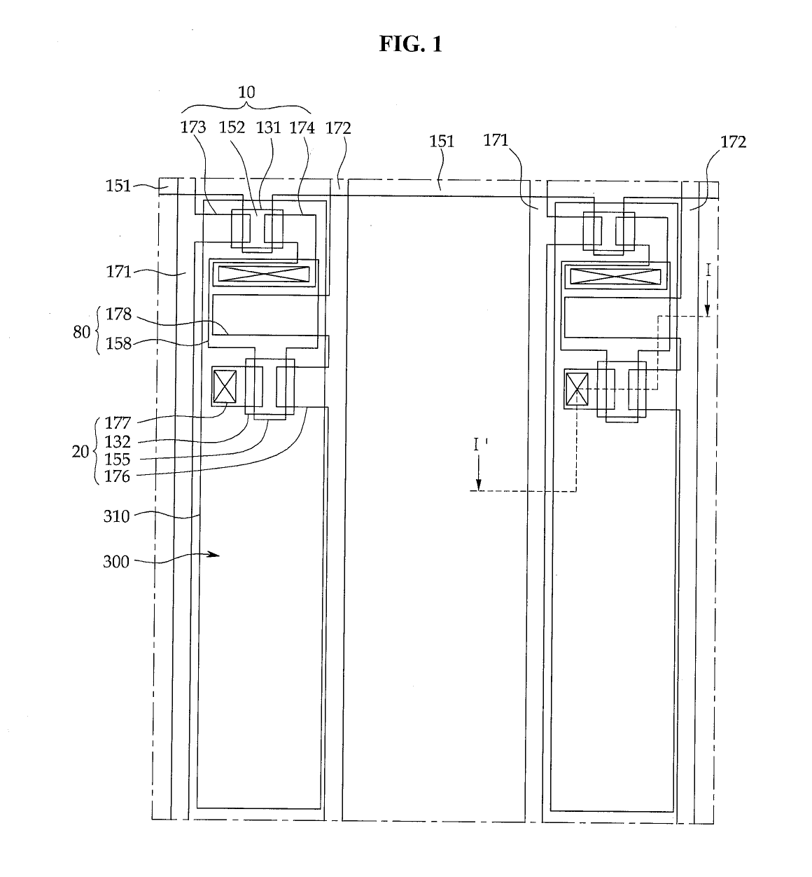

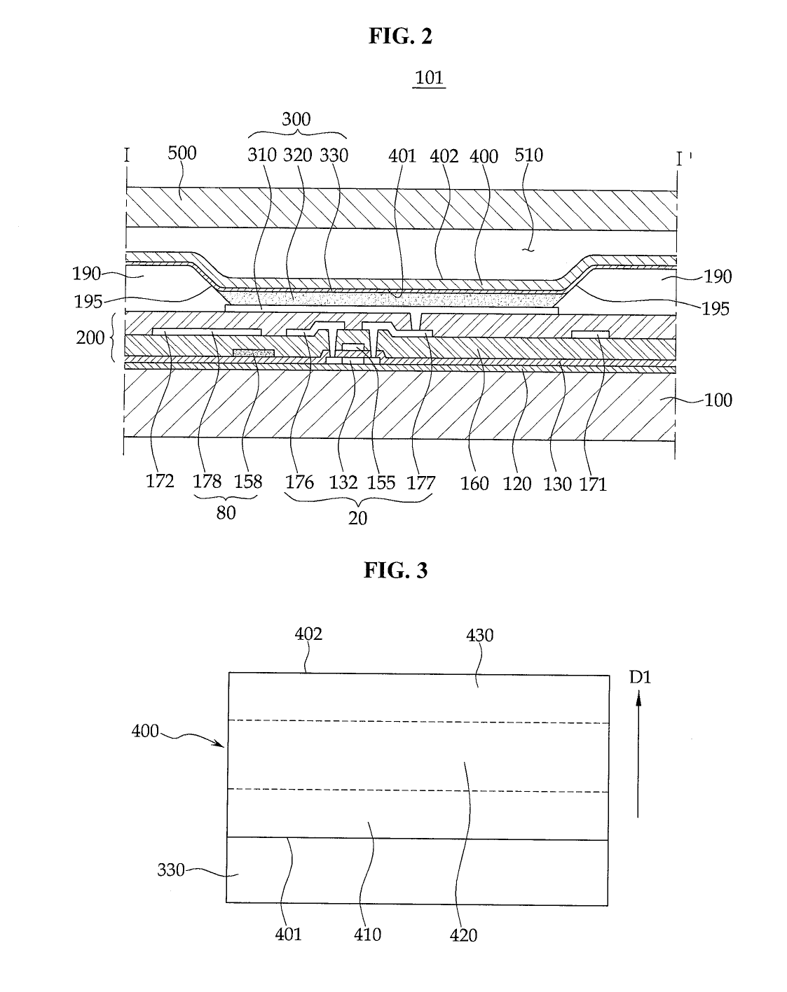

Hereinafter, a first embodiment of the present invention will be described with reference to FIGS. 1 and 2.

As illustrated in FIGS. 1 and 2, an organic light emitting diode display 101 according to the first embodiment of the present invention may include a first substrate 100, a wiring part 200, an organic light emitting diode 300, and a capping layer 400. The organic light emitting diode display 101 may further include a buffer layer 120 and a pixel defining layer 190.

The first substrate 100 may include an insulating substrate including glass, quartz, ceramic, and/or plastic. However, the first embodiment of the present invention is not limited thereto, and the first substrate 100 may also include a metal material such as stainless steel.

The buffer layer 120 may be disposed on the first substrate 100. Further, the buffer layer 120 may include various inorganic films and/or organic films. The buffer layer 120 may serve to planarize a surface (e.g., a surface of the first substrate 100) while preventing undesirable elements (e.g., impurities or moisture) from penetrating into the wiring part 200 or the organic light emitting diode 300. However, the buffer layer 120 is not always present and may be omitted according to kinds of the first substrate 100 and process conditions thereof.

The wiring part 200 may be disposed on the buffer layer 120. Further, the wiring part 200 may include a plurality of thin film transistors 10 and 20 and drives the organic light emitting diode 300. That is, the organic light emitting diode 300 displays an image by emitting light according to a driving signal that is received from the wiring part 200.

FIGS. 1 and 2 illustrate an active matrix (AM) organic light emitting diode display 101 with a 2Tr-1 Cap structure having two thin film transistors (TFT) 10 and 20 and one capacitor 80 in one pixel. However, the first embodiment of the present invention is not limited thereto. For example, the organic light emitting diode display 101 may have three or more thin film transistors and/or two or more capacitors in one pixel or may be configured to have various structures by further forming a separate wiring. Herein, the pixel is the smallest unit that displays an image, and the organic light emitting diode display 101 displays an image through (utilizing) a plurality of pixels.

A switching thin film transistor 10, a driving thin film transistor 20, a capacitor 80, and an organic light emitting diode 300 are formed in each pixel. Herein, a configuration including the switching TFT 10, the driving TFT 20, and the capacitor 80 is referred to as a wiring part 200. Further, a gate line 151 extending in one direction and a data line 171 and a common power source line 172 that are insulated from and cross (e.g., intersect) the gate line 151 are also formed on the wiring part 200. A pixel may be defined by the gate line 151, the data line 171, and the common power source line 172 as a boundary, but it is not limited thereto. The pixel may also be defined by a pixel defining layer (PDL).

The organic light emitting diode 300 includes a first electrode 310, an organic light emitting layer 320 on the first electrode 310, and a second electrode 330 on the organic light emitting layer 320. Holes and electrons are respectively injected from the first electrode 310 and the second electrode 330 into the organic light emitting layer 320. The injected holes and electrons are coupled with each other to form an exciton, and light is emitted when the exciton falls from an excited state to a ground state.

The capacitor 80 includes a pair of capacitor plates 158 and 178 with an interlayer insulating layer 160 interposed therebetween. Herein, the interlayer insulating layer 160 may include a dielectric material. Capacitance of the capacitor 80 is determined by a charge stored (e.g., energy charged) in the capacitor 80 and a voltage between both capacitor plates 158 and 178.

The switching TFT 10 includes a switching semiconductor layer 131, a switching gate electrode 152, a switching source electrode 173, and a switching drain electrode 174. The driving TFT 20 includes a driving semiconductor layer 132, a driving gate electrode 155, a driving source electrode 176, and a driving drain electrode 177. The semiconductor layers 131 and 132 are respectively insulated from the gate electrodes 152 and 155 by a gate insulating layer 130.

The switching TFT 10 acts as (is used or utilized as) a switching element configured to select a pixel to emit light. The switching gate electrode 152 is coupled to (e.g., connected to) the gate line 151. The switching source electrode 173 is coupled to (e.g., connected to) the data line 171. The switching drain electrode 174 is spaced from (e.g., spaced apart from) the switching source electrode 173 and is coupled to (e.g., connected to) the capacitor plate 158.

The driving TFT 20 applies driving power to the first electrode 310, that is, a pixel electrode, for light emission of the organic light emitting layer 320 of the OLED 300 in a selected pixel. The driving gate electrode 155 is coupled to (e.g., connected to) a capacitor plate 158 that is coupled to (e.g., connected to) the switching drain electrode 174. The driving source electrode 176 and the other capacitor plate 178 are each coupled to (e.g., connected to) the common power source line 172. The driving drain electrode 177 is coupled to (e.g., connected to) the first electrode 310, which is a pixel electrode of the OLED 300, through a contact opening (e.g., a contact hole).

With the above-described structure, the switching TFT 10 is driven by a gate voltage applied to the gate line 151 to transmit a data voltage applied to the data line 171 to the driving TFT 20. A voltage corresponding to a difference between a common voltage applied from the common power source line 172 to the driving TFT 20 and the data voltage transmitted from the switching TFT 10 is stored in the capacitor 80, and a current corresponding to the voltage stored in the capacitor 80 flows to the OLED 300 through the driving TFT 20, so that the OLED 300 emits light.

The OLED 300 emits light in accordance with a driving signal transmitted from the wiring part 200. Further, the OLED 300 includes the first electrode 310 (e.g., an anode that injects holes), the second electrode 330 (e.g., a cathode that injects electrons), and the organic emission layer 320 between the first electrode 310 and the second electrode 330. That is, the first electrode 310, the organic emission layer 320, and the second electrode 330 are sequentially laminated to form the OLED 300. However, the first embodiment of the present invention is not limited thereto. For example, the first electrode 310 may be a cathode and the second electrode 330 may be an anode.

According to the first embodiment of the present invention, the first electrode 310 is configured to be a reflective layer, and the second electrode 330 is configured to be a transflective layer. Therefore, light generated in the organic emission layer 320 is emitted by passing through the second electrode 330. That is, the OLED display 101 has a top-emission structure according to the first embodiment of the present invention.

The reflective layer and the transflective layer may be made of metal, for example, magnesium (Mg), silver (Ag), gold (Au), calcium (Ca), lithium (Li), chromium (Cr), aluminum (Al), and/or an alloy thereof. In this case, characteristics of the reflective layer and the transflective layer are determined by their respective thicknesses. The transflective layer may generally have a thickness of about 200 nm or less. The thinner the transflective layer, the higher the transmittance of light, and the thicker the transflective layer, the lower the transmittance of light.

Further, the first electrode 310 may include a transparent conductive layer. That is, the first electrode 310 may have a multilayer structure including a reflective layer and a transparent conductive layer. The transparent conductive layer of the first electrode 310 may be disposed between the reflective layer and the organic emission layer 320. Further, the first electrode 310 may have a triple-layer structure with a transparent conductive layer, a reflective layer, and a transparent conductive layer that are sequentially laminated. However, the first electrode 310 may include only the transparent conductive layer. In this case, the first electrode 310 may be a transparent electrode.

The transparent conductive layer may be made of a transparent conductive oxide (TCO) material (e.g., indium tin oxide (ITO), indium zinc oxide (IZO), zinc oxide (ZnO), and/or indium oxide (In₂O₃)). The transparent conductive layer has a relatively high work function. Therefore, in the case where the first electrode 310 includes the transparent conductive layer, hole injection may be smoothly performed through the first electrode 310.

Meanwhile, the second electrode 330 may be formed of a transparent conductive layer. In this case, the second electrode 330 may serve as an anode for hole injection, and the first electrode 310 may serve as a cathode formed of a reflective layer.

At least one of a hole injection layer (HIL) and a hole transporting layer (HTL) may be disposed between the first electrode 310, configured to serve as an anode, and the organic emission layer 320, and at least one of an electron transporting layer (ETL) and an electron injection layer (EIL) may be disposed between the second electrode 330, configured to serve as a cathode, and the organic emission layer 320.

Another layer may be further disposed between the organic emission layer 320 and the first electrode 310 and/or between the organic emission layer 320 and the second electrode 330.

The pixel definition layer 190 has an opening 195. The opening 195 of the pixel definition layer 190 exposes a portion of the first electrode 310. The organic emission layer 320 and the second electrode 330 are sequentially laminated in the opening 195 of the pixel definition layer 190. Herein, the second electrode 330 is further formed on the pixel definition layer 190 as well as the organic emission layer 320. The hole injection layer, the hole transporting layer, the electron transporting layer, and/or the electron injection layer may also be disposed in the opening 195 of the pixel definition layer 190 and between the first electrode 310 and the second electrode 330. The organic light emitting diode 300 emits light in the organic emission layer 320 disposed inside the opening 195 of the pixel definition layer 190. In other words, the opening 195 of the pixel definition layer 190 defines a light emission region.

The capping layer 400 may be disposed on the OLED 300. The capping layer 400 may play a role in effectively emitting light generated in the organic emission layer 320 and protecting the OLED 300.

The capping layer 400 may have a gradient of refractive index. For example, the capping layer 400 has a first surface 401 toward or facing the OLED 300 and a second surface 402 opposite the first surface 401 (e.g., facing oppositely away from the OLED 300), and the capping layer 400 may be configured to have a refractive index that varies (e.g., gradually varies or varies with a gradient of refractive index) along a thickness direction from the first surface 401 toward the second surface 402.

The direction from the first surface 401 toward the second surface 402 is referred to as the “thickness direction” of the capping layer 400, and the first surface 401 of the capping layer 400 is disposed on the second electrode 330 of the OLED 300 by being in contact therewith.

For example, a refractive index of the capping layer 400 may become gradually higher (e.g., gradually increasing) from the first surface 401 toward the second surface 402. In this case, the first surface 401 may have a refractive index of about 1.3 to about 1.8, and the second surface 402 may have a refractive index of about 1.8 to about 2.7.

However, the refractive index of the capping layer 400 may become gradually lower (e.g., gradually decrease) from the first surface 401 toward the second surface 402. In this case, the first surface 401 may have a refractive index of about 1.8 to about 2.7, and the second surface 402 may have a refractive index of about 1.3 to about 1.8.

The capping layer 400 may include the highest refractive index and the lowest refractive index therein because its refractive index varies gradually (e.g., varies with a gradient of refractive index) along the thickness direction. The difference between the highest refractive index and the lowest refractive index in the capping layer 400 may be in a range of about 0.1 to about 1.0. In other words, the capping layer 400 may exhibit a difference in refractive index of about 0.1 to about 1.0.

Further, as illustrated in FIG. 3, the capping layer 400 may be divided into a plurality of areas 410, 420, and 430. Any area among the plurality of areas 410, 420, and 430 may have a refractive index that may vary gradually along the thickness direction thereof. For example, in FIG. 3, the boundary areas 410 and 430 of the capping layer 400 may have a substantially constant refractive index, and the middle area 420 may have a refractive index varying gradually (e.g., may vary with a gradient) along the thickness direction thereof. On the other hand, the middle area 420 may have a substantially constant refractive index, and the boundary areas 410 and 430 of the capping layer 400 may have a refractive index varying gradually from each boundary area 410 and 430 toward the first surface 401 and the second surface 402, respectively.

The capping layer 400 is divided into three areas 410, 420, and 430 illustrated by dashed lines in FIG. 3. However, the capping layer 400 is merely illustrated as being randomly divided to help understanding of the present invention, and the actual capping layer 400 does not include an interface or boundary therein, but includes an area in which a refractive index varies gradually. Further, a direction D1 indicated by the arrow shows the thickness direction in FIG. 3.

The capping layer 400 may be made of a capping material, and inorganic and/or organic materials having light transmission characteristics may be used (utilized) as the capping material. For example, the capping layer 400 may be formed of an inorganic layer, an organic layer and/or may include an organic layer containing inorganic particles.

The capping layer 400 may include at least two capping materials having different refractive indices. For example, high refractive index and low refractive index materials may be used together for the capping material. The high refractive index and low refractive index materials may be an organic material and/or an inorganic material.

The capping material including the low refractive index material, namely a first capping material, may have a refractive index of about 1.3 to about 1.8.

The inorganic material having the low refractive index may include, for example, silicon oxide and/or magnesium fluoride.

The organic material having the low refractive index may include, for example, acrylic, polyimide, a polyamide, and/or Alq₃ [Tris(8-hydroxyquinolinato)aluminum].

The capping material including the high refractive index material, namely a second capping material, may have a refractive index of about 1.8 to about 2.7.

The inorganic material having the high refractive index may include, for example, zinc oxide, titanium oxide, zirconium oxide, niobium oxide, tantalum oxide, tin oxide, nickel oxide, silicon oxide, indium nitride, and/or gallium nitride.

Further, the organic material having the high refractive index may include, for example, poly(3,4-ethylenedioxythiophene) (PEDOT), 4,4′-bis[N-(3-methylphenyl)-N-phenylamino]biphenyl (TPD), 4,4′,4″-tris[N-3-methylphenyl-N-phenylamino]triphenylamine (m-MTDATA), 1,3,5-tris[N,N-bis(2-methylphenyl-amino]-benzene(o-MTDAB), 1,3,5-tris[N,N-bis(3-methylphenyl-amino]-benzene (m-MTDAB), 1,3,5-tris[N,N-bis(4-methylphenyl)-amino]-benzene (p-MTDAB), 4,4′-bis[N,N-bis(3-methylphenyl)-amino]-diphenylmethane (BPPM), 4,4′-N,N′-dicarbazole-1,1′-biphenyl (CBP), 4,4′,4″-Tris(N-carbazol-9-yl)triphenylamine (TCTA), 2,2′,2″-(1,3,5-benzentolyl)tris-1-[phenyl-1H-benzoimidazol] (TPBI), and/or 3-(4-biphenyl)-4-phenyl-5-tert-butylphenyl-1,2,4-triazole (TAZ).

In the first embodiment of the present invention, the material used for the high refractive index and low refractive index materials is not limited to the above described examples. Therefore, the capping layer 400 may be made of various materials that are known to those skilled in the art.

The capping layer 400 may have a thickness of about 80 nm to about 500 nm and may also have a thickness of 500 nm or more (e.g., about 600 nm to about 900 nm or more) in order to fully protect the organic light emitting diode 300.

The capping layer 400 may be manufactured by any suitable method that is known in the art, and for example, it may be formed by deposition. In the deposition process for the capping layer 400, the high refractive index and low refractive index materials may be used (utilized) together (e.g., utilized or deposited concurrently), and a deposition amount or deposition ratio of each of the high refractive index and low refractive index materials may be adjusted to manufacture the capping layer 400 including an area having a gradient of the refractive index along the thickness direction. The method for manufacturing the capping layer 400 will be described below in more detail with respect to a method for manufacturing an organic light emitting diode display.

A second substrate 500 may be disposed on the capping layer 400.

The second substrate 500 may be a transparent insulating substrate including glass, quartz, ceramic, and/or plastic. The second substrate 500 may be bonded and sealed to the first substrate 100 so as to cover the OLED 300. A sealant may be disposed at an edge of the first substrate 100 and the second substrate 500 to seal them. In this case, the second substrate 500 may be spaced from (e.g., spaced apart from) the OLED 300.

Referring to FIG. 2, an air layer 510 may be disposed in the space between the second substrate 500 and the OLED 300. The air layer 510 may have a lower refractive index than that of the capping layer 400.

By the above-described structure, the organic light emitting diode display 101 according to the first embodiment of the present invention may include the capping layer 400 having a gradient of the refractive index along the thickness direction.

The organic light emitting diode display 101 shown in FIG. 2 is a top-emission display, and light generated in the organic emission layer 320 is emitted by passing through the second electrode 330, the capping layer 400, the air layer 510, and the second substrate 500.

The light generated in the organic emission layer 320 passes through an interface between layers during the propagation process, but the light may fail to propagate through the interface between layers and may be reflected. For example, the light generated from the organic emission layer 320 may pass through an interface between the organic emission layer 320 and the second electrode 330, an interface between the second electrode 330 and the capping layer 400, an interface between the capping layer 400 and the air layer 510, and an interface between the air layer 510 and the second substrate 500, but the light may be reflected at one or more of the interfaces.

For example, the light may be reflected at the interface between the capping layer 400 and the air layer 510 or the light may be reflected at the interface between the second electrode 330 and the capping layer 400, and after propagating through the second electrode 330 and the organic emission layer 320, the light may again be reflected at an interface between the first electrode 310 and the organic emission layer 320.

As described above, repeated reflection of light may occur at interfaces between respective layers, and in the process, many light waves may be resonated. In the case where such resonance occurs, light is amplified such that an amount of light emitted outside increases. By virtue of such a resonance effect, the OLED display 101 may effectively amplify light, thereby improving light extraction efficiency thereof.

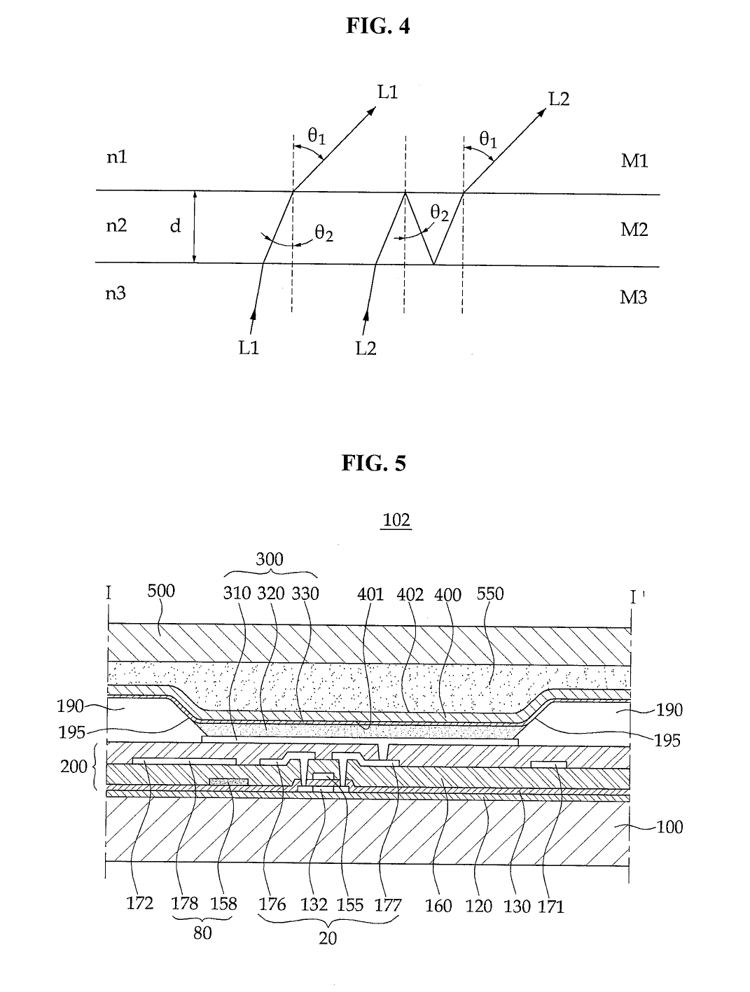

Referring to FIG. 4, reflectivity of light that is normally or perpendicularly incident on an interface between a layer M1 having a refractive index of n1 and another layer M2 having a refractive index of n2 may be calculated by the following formula:

Reflectance=(n2−n1)²/(n2+n1)²

In the above formula, factors that determine a refractive index is the sum of the refractive indices (n1 and n2) of each layer and the difference therebetween, but it may be understood that the difference between the refractive indices (n1 and n2) is a primary factor. Accordingly, the greater the difference between refractive indices of two layers having an interface therebetween, the greater the reflectance, and a relatively high reflectance may increase a possibility of resonance.

In the case where reflections repeatedly occur at interfaces, a light path increases in length. For example, FIG. 4 illustrates light L1 that is not reflected at an interface between the layer M1 and the layer M2 and propagates from the layer M2 to the layer M1, and light L2 that is reflected once each at two interfaces of the layer M2 and then propagates through the layer M1. When a thickness of the layer M2 is “d” and an angle of incidence at which light is incident on the interface between the layer M1 and the layer M2 is “θ₂,” the path of light L2 that is reflected once each at both interfaces of the layer M2 and then incident on the layer M1 has a path difference of “2d/cos θ₂” compared with the path of light L1 that is not reflected in the layer M2 and then is incident on the layer M1. In the case where light incident on the layer M2 is reflected twice in the layer M2 and then incident on the layer M1, the path difference is “4d/cos θ₁,” and thus, the path difference increases with the increasing number of reflections. Further, in the case where refractive index n1 of the layer M1 is lower than refractive index n2 of the layer M2, angle of incidence θ₁ at which light is incident on the layer M1 increases more than angle of incidence θ₂ at which light is incident on the layer M1.

Due to the difference in light path, white angular dependence may be recognized by a viewer. The white angular dependence is a phenomenon in which when white light is emitted from an organic light emitting diode display, the white light is visible when viewed from the front of the display but blue light is visible when viewed from a side of the display due to light wavelength shift. In order to reduce the white angular dependence phenomenon, the path difference of light emitted from an organic light emitting diode display should be decreased, and thus, the difference between refractive indices at an interface should be reduced.

As described above, improved light extraction efficiency due to resonance and increased or improved white angular dependence to improve the display characteristics are complementary to each other.

In order to increase light extraction efficiency and prevent the white angular dependence phenomenon from being increased (and/or to reduce white angle dependency), refractive indices of the first surface 401 and the second surface 402 of the capping layer 400 may differ from each other in consideration of a refractive index of a layer adjacent to the capping layer 400. However, when the capping layer 400 is configured to have two or more layers with the refractive indices of the first surface 401 and the second surface 402 of the capping layer 400 different from each other, an interface may be formed in the capping layer 400 and reflection may occur at the interface.

In the organic light emitting diode display 101 according to an embodiment of the present invention, there is an area where a refractive index of the capping layer 400 varies (e.g., varies gradually) along a thickness direction from the first surface 401 of the capping layer 400 toward the second surface 402 thereof. A gradient of the refractive index exists in the capping layer 400, and therefore, an interface may not be formed in the capping layer 400 while the first surface 401 and the second surface 402 of the capping layer 400 have refractive indices different from each other.

The refractive indices of the first surface 401 and the second surface 402 of the capping layer 400 may be adjusted by considering refractive indices of layers adjacent to each of the first surface 401 and the second surface 402.

For instance, in the case where the refractive index of the first surface 401 of the capping layer 400 is adjusted, thereby reducing the difference between the refractive indices of the second electrode 330 and the first surface 401 of the capping layer 400, light emitted from the organic emission layer 320 is easily incident on the capping layer 400, and thus, a path difference of light may only be slightly increased. In this case, large resonance of the light may not occur between the second electrode 330 and the first electrode 310. In the case where the second surface 402 of the capping layer 400 has a high refractive index, the air layer 510 and the second surface 402 have a large difference in refractive index and reflectance increases at the interface of the second surface 402 and the air layer 510, so that light resonance may occur in the capping layer 400.

On the other hand, in the case where the refractive index of the first surface 401 of the capping layer 400 is adjusted, thereby increasing the difference between refractive indices of the second electrode 330 and the first surface 401 of the capping layer 400, light generated in the organic emission layer 320 is repeatedly reflected between the second electrode 330 and the first electrode 310, such that resonance of the light may occur. In this case, the light amplified due to the resonance may be incident on the capping layer 400. However, in the case where the second surface 402 of the capping layer 400 has a lower refractive index, the difference between refractive indices of the air layer 510 and the second surface 402 is reduced or relatively small, and light in the capping layer 400 may easily propagate to the air layer 510. In this case, reflection of light may decrease in the capping layer 400, thereby reducing the light path difference.

Hereinafter, a second embodiment of the present invention will be described with reference to FIG. 5.

As illustrated in FIG. 5, an organic light emitting diode display 102 according to the second embodiment of the present invention includes a filler 550 in a space between the capping layer 400 and the second substrate 500. The filler 550 may fill an internal space of the organic light emitting diode display 102 instead of the air layer 510.

The filler 550 may include an organic material (e.g., a polymer). The filler 550 may have a refractive index that is lower or higher than the second surface 402 of the capping layer 400 or that is identical thereto. A material of the filler 550 may be selected by considering the refractive index of the second surface 402 of the capping layer 400.

Further, the material of the filler 550 may be selected according to a refractive index of the second substrate 500. For instance, in the case where the second substrate 500 is a glass substrate having a refractive index of about 1.5, a polymer having a refractive index of about 1.5 may be used as a material of the filler 550 (e.g., poly(methyl methacrylate) (PMMA)).

In addition, the filler 550 fills the internal space of the organic light emitting diode display 102, thereby improving strength and durability of the organic light emitting diode display 102.

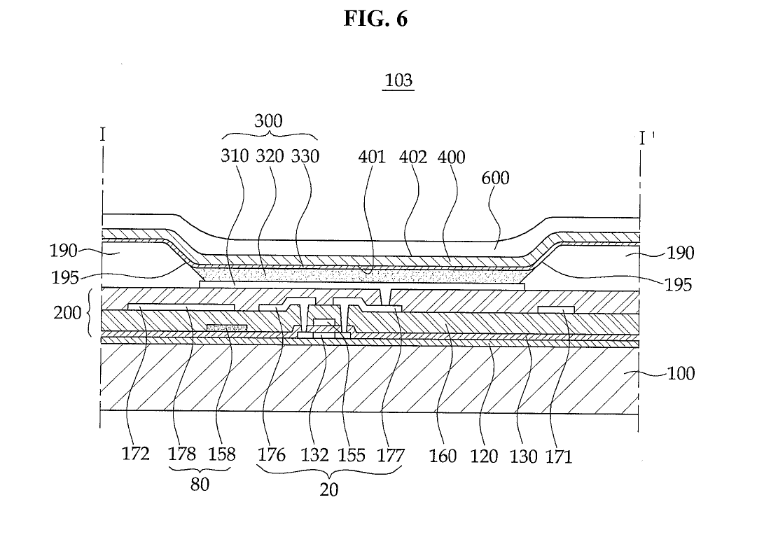

Hereinafter, a third embodiment of the present invention will be described with reference to FIG. 6.

As illustrated in FIG. 6, an organic light emitting diode display 103 according to the third embodiment of the present invention includes a thin film encapsulation layer 600 on the capping layer 400.

The thin film encapsulation layer 600 may have a structure in which an organic layer and an inorganic layer are alternately disposed thereon. The thin film encapsulation layer 600 is configured to protect the capping layer 400 and the organic light emitting diode 300.

A refractive index of the second surface 402 of the capping layer 400 may be adjusted according to a refractive index of a first layer of the thin film encapsulation layer 600 which is in contact (e.g., direct contact) with the capping layer 400. However, the refractive index of the first layer of the thin film encapsulation layer 600 may be adjusted by considering the refractive index of the second surface 402 of the capping layer 400. There may be a large or small difference between the refractive indices of the second surface 402 of the capping layer 400 and the first layer of the thin film encapsulation layer 600 or there may be no substantial difference between the refractive indices thereof.

The first layer of the thin film encapsulation layer 600, which is in contact (e.g., direct contact) with the capping layer 400, may include an inorganic layer or an organic layer.

Further, an embodiment of the present invention provides a method of manufacturing an organic light emitting diode display including a capping layer with a gradient of refractive index along a thickness direction.

For example, according to an embodiment of the present invention, the manufacturing method of an organic light emitting diode display includes forming the organic light emitting diode 300 on the first substrate 100 and forming the capping layer 400 on the organic light emitting diode 300.

Before the organic light emitting diode 300 is formed on the first substrate 100, the wiring part 200 may be formed on the first substrate 100. The wiring part 200 has been previously described, and thus, further description thereof will be omitted.

The forming of the organic light emitting diode 300 includes forming the first electrode 310 on the first substrate 100, forming the organic emission layer 320 on the first electrode 310, and forming the second electrode 330 on the organic emission layer 320. At least one of the hole injection layer and the hole transporting layer may be further formed on the first electrode 310 after the forming of the first electrode 310 and before the forming of the organic emission layer 320. Further, at least one of the electron injection layer and the electron transporting layer may be further formed on the organic emission layer 320 after the forming of the organic emission layer 320 and before the forming of the second electrode 330.

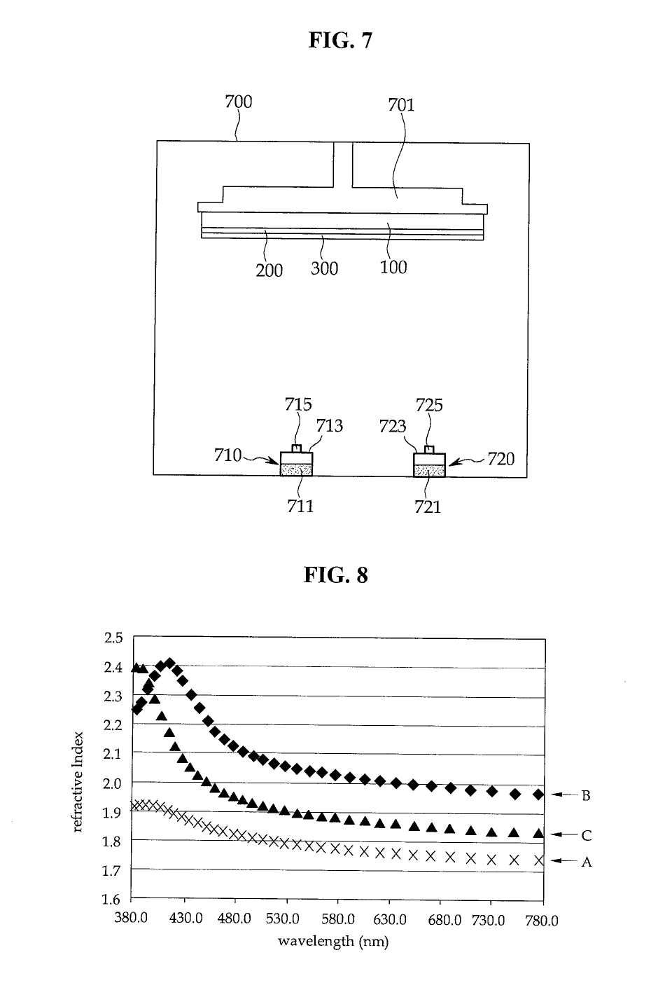

The capping layer 400 may be formed by deposition. FIG. 7 shows a deposition apparatus configured to perform a deposition process according to an embodiment of the present invention.

The capping layer 400 may be formed by using (utilizing) a first capping material 711 and a second capping material 721 having a higher refractive index than that of the first capping material 711. For example, a deposition may be performed by using (utilizing) the first capping material 711 and the second capping material 721, namely a co-deposition. As the deposition is performed, a deposition ratio of the first capping material 711 and the second capping material 721 may vary gradually (e.g., varies with a gradient), and accordingly, the capping layer may be formed with a gradient of refractive index along a thickness direction.

The deposition apparatus includes a chamber 700, a substrate supporter 701 provided in the chamber 700, and deposition furnaces 710 and 720. The deposition is performed in the chamber 700 where the first substrate 100 provided with the organic light emitting diode 300 on one surface thereof is supported by the substrate supporter 701.

The first deposition furnace 710 with the first capping material 711 and the second deposition furnace 720 with the second capping material 721 are provided at a bottom of the chamber 700.

The deposition furnaces 710 and 720 include body portions 713 and 723, configured to accommodate the capping materials 711 and 721, and deposition nozzles 715 and 725 having openings configured to emit the capping materials 711 and 721. Furthermore, a heating unit configured to heat the body portions 713 and 723 may be provided in the deposition furnaces 710 and 720.

The deposition apparatus illustrated in FIG. 7 is used (utilized) to deposit an organic material, but the capping material deposited by the deposition apparatus is not limited to only the organic material.

The first capping material 711 deposited to form the capping layer 400 may have a refractive index of about 1.3 to about 1.8, and the second capping material 721 may have a refractive index of about 1.8 to about 2.7. In other words, the first capping material 711 is a low refractive index material and the second capping material 721 is a high refractive index material for the purpose of forming the capping layer 400.

Because the high refractive index and low refractive index materials used for the capping layer 400 have been previously described, further description thereof will be omitted. Meanwhile, the refractive index of the capping layer 400 may vary depending on deposition conditions although the same materials are used.

In order to perform the deposition, the deposition furnaces 710 and 720 are heated by the heating unit, and then the capping materials 711 and 721 are evaporated and emitted from the deposition furnaces 710 and 720 through the deposition nozzles 715 and 725. The emitted capping materials 711 and 721 are deposited on the organic light emitting diode 300 on the first substrate 100, thereby forming the capping layer 400.

The deposition furnaces 710 and 720 or the substrate may move in one direction when the deposition is performed. Herein, in the case where the first deposition furnace 710 and the second deposition furnace 720 move in the chamber 700, a deposition ratio of the first capping materials 711 and the second capping materials 721 may vary gradually as the deposition is performed due to an emission time (e.g., an emission rate) difference or a distance between furnaces 710 and 720.

Further, the deposition ratio of the first capping materials 711 and the second capping materials 721 deposited on the organic light emitting diode 300 may be adjusted or varied by controlling release speed (time) of the first capping materials 711 and the second capping materials 721 from the deposition furnaces 710 and 720.

A heating temperature of the deposition furnaces 710 and 720 may be individually adjusted to control evaporation speed of the capping materials 711 and 721, so that the deposition ratio of the first capping materials 711 and the second capping materials 721 may be adjusted or varied. A size of the opening of the deposition nozzles 715 and 725 may be adjusted or varied to control a released (or emitted) amount of the capping materials 711 and 721 from the deposition furnaces 710 and 720, so that the deposition ratio of the first capping materials 711 and the second capping materials 721 may be adjusted or varied.

For example, one of the released amounts (e.g., emitted amount or rate) of the first capping materials 711 and the second capping materials 721 from the deposition furnaces 710 and 720 remains unchanged and the other released amount (e.g., emitted amount or rate) is changed, so that the deposition ratio may be adjusted. Further, the deposition ratio may be adjusted by controlling the respective released amounts (e.g., emitted amounts or rates) of the first capping materials 711 and the second capping materials 721 from the deposition furnaces 710 and 720.

Those skilled in the art may select a suitable method to adjust the deposition ratio of the capping materials 711 and 721.

For instance, the deposition may be performed by using (utilizing) capping materials A, B, and C that have refractive indices shown in FIG. 8. FIG. 8 is a graph showing refractive indices of capping materials A, B, and C including low, high, and middle refractive index materials, respectively, according to wavelength of light. Capping materials A, B, and C may include a pyridine-based deposition material.

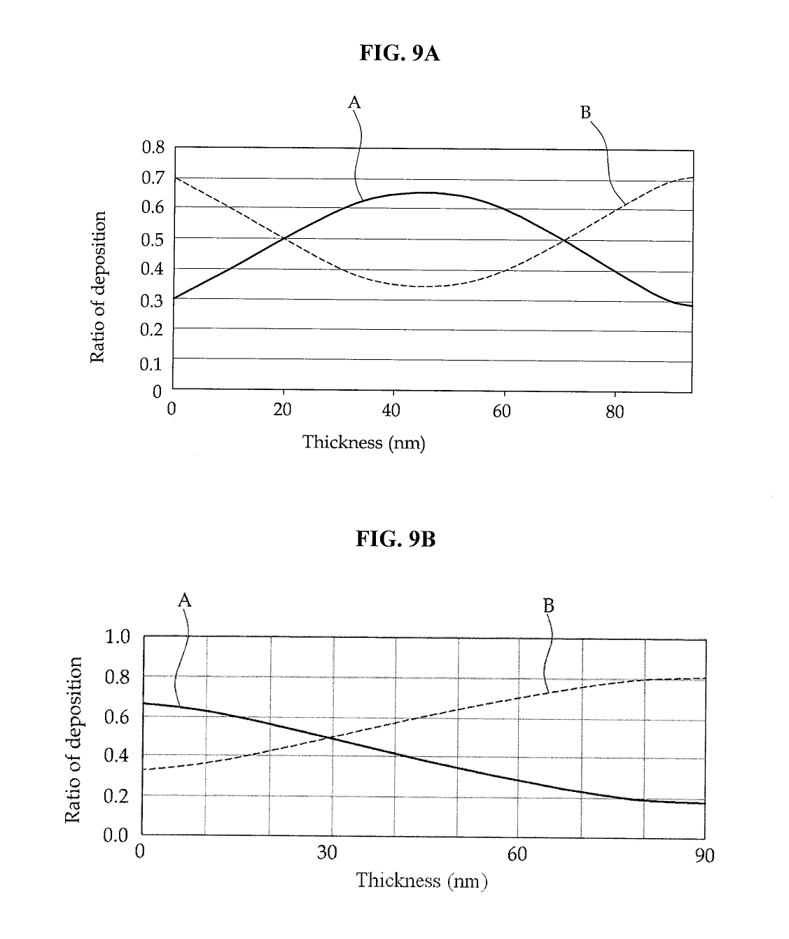

FIGS. 9A and 9B are graphs showing deposition profiles in the case of forming the capping layer 400 using (utilizing) capping materials A and B shown in FIG. 8. The horizontal axis indicates a thickness and the vertical axis indicates a deposition ratio of capping materials A and B for each thickness shown in the graphs of FIGS. 9A and 9B.

In order to obtain the deposition profile shown in FIG. 9A, for example, a deposition may be performed by first moving the deposition furnace containing deposition material B, then moving the deposition furnace containing deposition material A while the deposition furnace containing deposition material B moves, and the deposition may be completed by again moving the deposition furnace containing deposition material B. The deposition may be performed by using (utilizing) two deposition furnaces containing deposition material B and one deposition furnace containing deposition material A in the order of deposition materials B, A, and B.

In order to obtain the deposition profile shown in FIG. 9B, for example, a deposition may be performed by first moving the deposition furnace containing deposition material A and then further moving the deposition furnace containing deposition material B while the deposition furnace containing deposition material A moves.

Those skilled in the art may easily select a deposition method to obtain a deposition profile such as that shown in FIG. 9A or 9B.

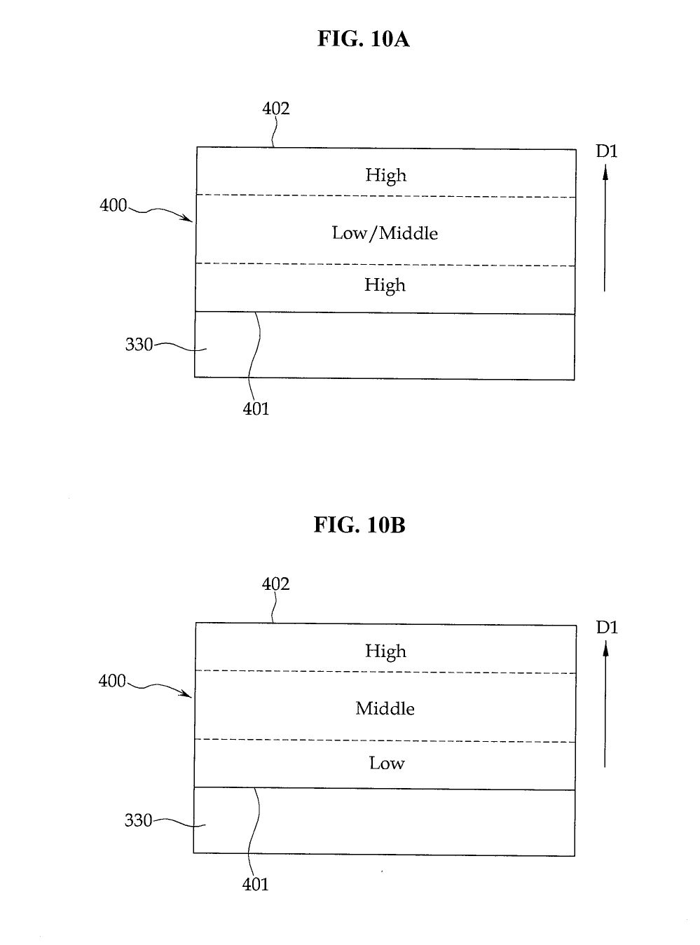

A deposition performed to achieve the profile shown in FIG. 9A may result in the capping layer 400 shown in FIG. 10A, and a deposition performed to achieve the profile shown in FIG. 9B may result in the capping layer 400 shown in FIG. 10B. FIGS. 10A and 10B illustrate areas that are divided by dashed lines, but this is for the purpose of helping understanding of a configuration of the capping layer 400 and does not mean that an interface is formed in the capping layer 400. The high, middle, and low areas of FIGS. 10A and 10B connote high, middle, and low refractive index portions, respectively.

For example, as shown in FIG. 9B, as the deposition is performed, a deposition ratio of capping material B gradually increases and a deposition ratio of capping material A gradually decreases. In this case, as the deposition is performed, a refractive index of a deposition surface included in the capping layer 400 increases. As a result, the capping layer 400 in which the first surface 401 has a lower refractive index than that of the second surface 402 may be formed (see FIG. 10B).

Hereinafter, comparisons will be made between light properties of a capping layer including a high refractive index material, a capping layer including a low refractive index material, and a capping layer including an area having a gradient of refractive index.

Table 1 shows color coordinator values and efficiencies of a capping layer (Experiment example 1) manufactured by using (utilizing) deposition materials A and B and having the deposition profile shown in FIG. 9A, a capping layer (Experiment example 2) having the deposition profile shown in FIG. 9B, and a capping layer (Comparison example 1) made only of deposition material B, that is, a high refractive index material.

R(x), G(x), and B(y) in Table 1 are x-coordinate and y-coordinate values in a color coordinate of International Commission on Illumination (CIE) with respect to red, green, and blue color lights, respectively, passing through the manufactured capping layer.

R(Eff), G(Eff), and B(Eff) in Table 1 refer to light efficiencies calculated by intensity of light (cd) according to an input current (A) of red, green, and blue color lights, respectively, and W(Eff) refers to an efficiency of white light.

TABLE 1

| Detail | R (x) | R (Eff) | G (x) | G (Eff) | B (y) | B (Eff) | W (Eff) |
|---|---|---|---|---|---|---|---|
| Experiment | 0.66528 | 54.3 | 0.25644 | 101.8 | 0.05576 | 116.8 | 41.5 |
| example 1 | | | | | | | |
| Experiment | 0.6613 | 51.2 | 0.2481 | 99.6 | 0.05076 | 123.0 | 41.8 |
| example 2 | | | | | | | |
| Comparison | 0.657 | 56.5 | 0.235 | 95.6 | 0.046 | 126.2 | 42.7 |
| example 1 | | | | | | | |

As can be seen in Table 1, in the case using (utilizing) the capping layer having a gradient of the refractive index (Experiment examples 1 and 2), a light efficiency similar to that of the capping layer made of a high refractive index material (Comparison example 1) may be achieved. In the case of using (utilizing) a capping material having a low refractive index of less than about 1.8, the light efficiency of the white light is known to be about 36 and 37. Therefore, it can be understood that the capping layer having a gradient of the refractive index (Experiment examples 1 and 2) has a greater light efficiency than that of a capping layer made of a low refractive index material (Comparison example 2).

FIG. 11 is a graph comparing white angular dependence properties.

In the graph of FIG. 11, the horizontal axis indicates a viewing angle with respect to a front right angle of a display device (that is, normal or perpendicular to the display device), and the vertical axis indicates a variation (Δx) of an x value in a color coordinate. Further, in the above graph, Comparison examples 1 and 2 refer to white angular dependence properties of the capping layer manufactured by using (utilizing) capping materials B and A of FIG. 8, respectively, and Experiment examples 1 and 2 refer to white angular dependence properties of the capping layer having the deposition profiles of FIGS. 9A and 9B, respectively. As shown in FIG. 11, it may be understood that as a viewing angle becomes wider (that is, as the viewing angle increases), a color variation (Δx) of the capping layer made of a high refractive index material (Comparison example 1) increases. The capping layers of Experiment examples 1 and 2 exhibit improved white angular dependence properties compared to that of Comparison example 1.

Meanwhile, the capping layers of Experiment examples 1 and 2 each do not have a reduced white angular dependence phenomenon compared with that of the capping layer made of a low refractive index material (Comparison example 2), but exhibit greater light efficiency than that of the capping layer of Comparison example 2.

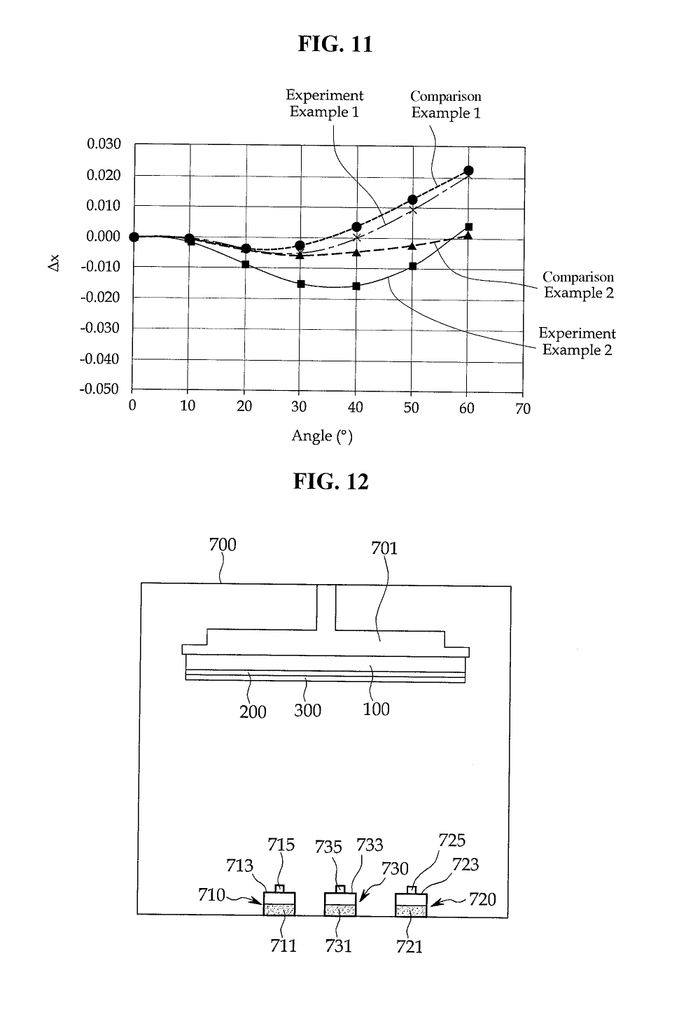

FIG. 12 is a schematic diagram showing a deposition apparatus according to another embodiment of the present invention. The deposition apparatus of FIG. 12 further includes a third deposition furnace 730 configured to deposit a third capping material 731. The third capping material 731 may be a material having a refractive index that is higher than that of the first capping material 711 and lower than that of the second capping material 721. In other words, in the deposition process to form the capping layer 400, the third capping material 731 having a refractive index that is higher than that of the first capping material 711 and lower than that of the second capping material 721 may also be used (utilized).

The third deposition furnace 730 includes a body portion 733 and a deposition nozzle 735 to accommodate a capping material in the same manner as the first and second deposition furnaces 710 and 720.

After the forming of the capping layer 400, the second substrate 500 may be disposed on the capping layer 400.

After the forming of the capping layer 400, the thin film encapsulation layer 600 may be further formed on the capping layer 400. The forming of the thin film encapsulation layer 600 may include alternately performing the acts of forming an organic layer and forming an inorganic layer.

The second substrate 500 and the thin film encapsulation layer 600 have been previously described, and thus, further description thereof will be omitted.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims and their equivalents.

What is claimed is:

1. An organic light emitting diode display comprising:
a first substrate;
an organic light emitting diode on the first substrate; and
a capping layer on the organic light emitting diode,
wherein the capping layer comprises a first surface facing the organic light emitting diode and a second surface opposite the first surface, and
wherein the capping layer has a gradient of refractive index that varies along a thickness direction from the first surface toward the second surface.

2. The organic light emitting diode display of claim 1, wherein the refractive index increases along the thickness direction.

3. The organic light emitting diode display of claim 2, wherein the refractive index at the first surface is in a range of about 1.3 to about 1.8, and the refractive index at the second surface is in a range of about 1.8 to about 2.7.

4. The organic light emitting diode display of claim 1, wherein the refractive index decreases along the thickness direction.

5. The organic light emitting diode display of claim 4, wherein the refractive index at the first surface is in a range of about 1.8 to about 2.7, and the refractive index at the second surface is in a range of about 1.3 to about 1.8.

6. The organic light emitting diode display of claim 1, wherein the refractive index decreases from a point in the capping layer along a direction toward each of the first surface and the second surface, respectively.

7. The organic light emitting diode display of claim 1, wherein the refractive index increases from a point in the capping layer along a direction toward each of the first surface and the second surface, respectively.

8. The organic light emitting diode display of claim 1, wherein the capping layer comprises a first capping material, a second capping material having a refractive index higher than the first capping material, and
wherein a content ratio of the first capping material and the second capping material varies with a gradient along the thickness direction.

9. The organic light emitting diode display of claim 1, wherein a difference between the highest refractive index and the lowest refractive index of the capping layer is in a range of about 0.1 to about 1.0.

10. The organic light emitting diode display of claim 1, further comprising a second substrate on the capping layer.

11. The organic light emitting diode display of claim 1, further comprising a thin film encapsulation layer on the capping layer.

12. A manufacturing method of an organic light emitting diode display, the method comprising:
forming an organic light emitting diode on a first substrate; and
forming a capping layer on the organic light emitting diode,
wherein the forming of the capping layer comprises depositing a first capping material and a second capping material having a refractive index higher than that of the first capping material on the organic light emitting diode, and
wherein a deposition ratio of the first capping material and the second capping material gradually varies as the depositing is performed.

13. The manufacturing method of claim 12, wherein the deposition ratio of the first capping material gradually increases as the depositing is performed.

14. The manufacturing method of claim 12, wherein the deposition ratio of the second capping material gradually increases as the depositing is performed.

15. The manufacturing method of claim 12, wherein a refractive index of the first capping material is in a range of about 1.3 to about 1.8.

16. The manufacturing method of claim 12, wherein a refractive index of the second capping material is in a range of about 1.8 to about 2.7.

17. The manufacturing method of claim 12, wherein the forming of the capping layer further comprises depositing a third capping material having a refractive index higher than that of the first capping material and lower than that of the second capping material.

18. The manufacturing method of claim 12, further comprising forming a thin film encapsulation layer on the capping layer after the forming of the capping layer.

19. The manufacturing method of claim 18, wherein the forming of the thin film encapsulation layer comprises alternately forming an organic layer and an inorganic layer.
